(19) United States
(12) Patent Application Publication
(10) Pub. No.: US 2022/0155352 A1
(43) Pub. Date: May 19, 2022

(54) LOW CURRENT HALL EFFECT SENSOR

(71) Applicant: Dima CHESKIS, (US)

(72) Inventors: Dima CHESKIS, Alfe Menashe (IL); Bagrat KHACHATRYAN, Haifa (IL); Yossi SHARON, Netanya (IL)

(21) Appl. No.: 17/440,903

(22) PCT Filed: Mar. 18, 2020
(86) PCT No.: PCT/IL2020/050319

§ 371 Date: Sep. 20, 2021

Related U.S. Application Data
(60) Provisional application No. 62/819,733, filed on Mar. 18, 2019.

(51) Int. Cl. G01R 15/20

(52) U.S. Cl. CPC G01R 15/202

(57) ABSTRACT

a Hall effect element; and a direct current (DC) current source connected to said Hall effect element, wherein: (i) said DC current source is isolated from an external power grid, and (ii) no more than one electronic component is connected in a current path between said DC current source and said Hall effect element.

### BACKGROUND

The invention relates to the field of electronics.

Many modern devices, such as smartphones, tablets, e-readers, GPS (Global Positioning System) units, and heart rate monitors, are controlled remotely and operated continuously for long stretches of time. These features come with a practical design constraint: the devices spend most of their time in a low-power sleep mode, using a battery or a DC (Direct Current) low-power bus to deliver current in the sub-milliampere (mA) range. When transmitting information, the devices switch to high-power radio frequency (RF) activity, and the current increases to the mA or even Ampere range. To control the switching, precise sensors must be used that are capable of measuring both low and high currents. Usually, a non-contact current control is done using Hall sensors. The current flowing through the Hall sensor creates a Perpendicular Hall voltage, which is proportional to the current and detectable through the material of the sensor.

The foregoing examples of the related art and limitations related therewith are intended to be illustrative and not exclusive. Other limitations of the related art will become apparent to those of skill in the art upon a reading of the specification and a study of the figures.

### SUMMARY

The following embodiments and aspects thereof are described and illustrated in conjunction with systems, tools and methods which are meant to be exemplary and illustrative, not limiting in scope.

There is provided, in an embodiment, a system comprising: a Hall effect element; and a direct current (DC) current source connected to said Hall effect element, wherein: (i) said DC current source is isolated from an external power grid, and (ii) no more than one electronic component is connected in a current path between said DC current source and said Hall effect element.

There is also provided in an embodiment, a method comprising: providing a Hall effect element; connecting said Hall effect element to a direct current (DC) current source, wherein: (i) said DC current source is isolated from an external power grid, and (ii) no more than one electronic component is connected in a current path between said DC current source and said Hall effect element; placing said Hall effect element in the presence of a magnetic field, such that said magnetic field passes through said Hall effect element in a specified direction; and measuring an output voltage of said current Hall element.

In some embodiments, the DC current source comprises a DC battery.

In some embodiments, no more than two electronic components are connected in the current path between said DC current source and said Hall effect element.

In some embodiments, the electronic components are selected from the group consisting of a current regulator and a resistor.

In some embodiments, the DC current source is connected to said Hall effect element using one of a four-point probe arrangement and a Hall bar arrangement.

In some embodiments, the Hall effect element is coupled to at least one of (i) a heat sink and (ii) a cryostat, each configured to reduce a temperature of said Hall effect element.

In some embodiments, the output voltage of said Hall effect element is adjusted based, at least in part, on a known output voltage response curve of said Hall effect element as a function of said temperature.

In some embodiments, the Hall effect element has a known Hall coefficient.

In some embodiments, the output voltage is amplified using an amplifier.

In some embodiments, the amplifier is a low noise amplifier.

In some embodiments, the Hall effect element comprises one of a (i) gallium arsenide (GaAs) element, and a (i) ferromagnetic element.

In some embodiments, the output voltage is detectable by a voltmeter.

There is further provided, in an embodiment, a system comprising: a magnetic element configured to displace mechanically in response to temperature changes; a Hall effect element placed within a first magnetic field generated by said magnetic element, such that said first magnetic field passes through said Hall effect element in a specified direction; and a direct current (DC) current source connected to said Hall effect element, wherein: (i) said DC current source is isolated from an external power grid, and (ii) no more than one electronic component is connected in a current path between said DC current source and said Hall effect element.

There is further provided, in an embodiment, a method comprising: providing a magnetic element configured to displace mechanically in response to temperature changes; placing a Hall effect element within a first magnetic field generated by said magnetic element, such that said first magnetic field passes through said Hall effect element in a specified direction; an connecting said Hall effect element to a direct current (DC) current source, wherein: (i) said DC current source is isolated from an external power grid, and (ii) no more than one electronic component is connected in a current path between said DC current source and said Hall effect element; and measuring an output voltage of said current Hall element.

In some embodiments, the magnetic element comprises a magnetized bi-metallic element.

In some embodiments, the Hall effect element is also placed within a second magnetic field generated by a permanent magnet.

In some embodiments, the magnetic element is thermally-coupled to a liquid tank, wherein a change in a temperature of a liquid contained in said liquid tank causes said machinal displacement, wherein a first correlation between said change in said temperature and said mechanical displacement is known.

In some embodiments, the mechanical displacement causes a change in said first magnetic field, wherein a second correlation between said mechanical displacement and said change in said first magnetic field is known.

In some embodiments, the change in said first magnetic field cause a change in an output voltage of said Hall effect element, wherein a third correlation between said change in said first magnetic field and said change in said output voltage is known.

In some embodiments, a temperature of the said liquid can be determined based, at least in part, on the output voltage and the first, second, and third correlations.

In some embodiments, the DC current source comprises a DC battery.

In some embodiments, the DC current source is connected to said Hall effect element using one of a four-point probe arrangement and a Hall bar arrangement.

In some embodiments, the Hall effect element comprises one of a gallium arsenide (GaAs) and a ferromagnetic element.

In some embodiments, the output voltage is detectable by a voltmeter.

In addition to the exemplary aspects and embodiments described above, further aspects and embodiments will become apparent by reference to the figures and by study of the following detailed description.

### BRIEF DESCRIPTION OF THE FIGURES

Exemplary embodiments are illustrated in referenced figures. Dimensions of components and features shown in the figures are generally chosen for convenience and clarity of presentation and are not necessarily shown to scale. The figures are listed below.

FIG. 1 illustrates an exemplary Hall effect sensor system, according to an embodiment;

FIG. 2 illustrates the noise spectral density of current source of a Hall effect sensor system, according to an embodiment;

FIG. 3 illustrates the effect of thermal fluctuations on Hall response;

FIG. 4A illustrates an experimental setup for a Hall effect sensor system, according to an embodiment;

FIGS. 4B-4C illustrate two different Hall effect arrangements used in an experimental setup for a Hall effect sensor system, according to an embodiment;

FIGS. 5, 6A-6D, and 7A-7B illustrate experimental results, according to an embodiment;

FIG. 8 illustrates the ferromagnetic Hall effect;

FIG. 9A schematically illustrates an external temperature sensing unit, according to an embodiment;

FIG. 9B schematically illustrates the function of a bimetallic element;

FIGS. 10A-10B and 11A-11B show the temperature of a magnetized element as a function of time, and an output voltage of a Hall effect sensor as a function of time, according to an embodiment;

FIGS. 12A-12B show a relationship between an output voltage of a Hall effect sensor and a temperature of a magnetized element, according to an embodiment; and

FIG. 13 shows a relationship between a temperature of a liquid inside a tank and a temperature of an outside wall of the tank.

### DETAILED DESCRIPTION

Disclosed herein is a Hall effect sensor system and associated method for the accurate non-contact measuring of low electric currents and/or low magnetic fields. In some embodiments, the present Hall effect sensor can accurately measure electric currents in the microampere (μA) range and/or magnetic fields in the range below 0.7 Tesla.

The present invention offers an easy-to-implement solution to accurately measuring very low currents, without the cost, complexity, and size penalties typically associated with existing methods and devices.

In some embodiments, the present Hall effect sensor may be effective in any application having a DC current source that is isolated from any external power grid. Thus, the present Hall effect sensor may use very low amounts of electrical current, and thus.

In some embodiments, the present Hall effect sensor may be deployed in a variety of applications, e.g., as a non-contact switch and/or temperature sensor.

In some embodiments, the present disclosure provides or efficient non-contact temperature measuring sensor having a linear response curve across a wide range of temperatures. In some embodiments, the temperature sensor of the present disclosure provides for a low cost, effective, and energy-efficient non-contact temperature sensor.

For example, in some embodiments, the present disclosure may be implemented as a temperature sensor for water heater tanks, such as in the context of solar water heater solutions.

Solar water heaters provide for a zero-emissions, zero-waste solution to water heating other, thus eliminating environmentally destructive practices used by traditional water heating methods. This advantage has been the major driving force in the adoption of solar water heaters. However, solar water heaters are at a disadvantage during days of little or no sunshine, which negatively impact the effectiveness of solar water heater systems.

Accordingly, solar thermal-based poly-generation systems (e.g., combining electricity and/or gas heating, as needed) are being developed to increase the market potential of solar thermal systems, and contribute to increased efficiency in the overall energy sector. However, poly-generation systems require intelligent controllers which manage the activation of the different heat generating modalities based on demand and availability. Specifically, smart controllers will need to forecast when and for how long the electrical/gas element needs to be activated, to meet demand while minimizing energy costs. For this purpose, it is necessary to measure water temperature inside the water tank. However, currently, accurate estimation of water temperature within a large tank requires a complicated system which consists of a number of temperature sensors placed in various spots within the tank.

Accordingly, the present disclosure provides for a non-contact Hall-effect-based temperature sensor which may be placed externally to the water tank and measure water temperature outside the boiler. The disclose temperature sensor provides for a linear response curve across a wide range of working temperatures.

As noted above, a Hall effect sensor is a transducer that varies its output voltage in response to a magnetic field generated by an electric current. Hall effect sensors are used, e.g., for magnetic field measuring, current sensing, proximity switching, positioning, and speed detection applications. Typical Hall sensor that usually works in the milliampere (mA) current range, cannot easily switch to the μA range because the signal to noise ratio (SNR) of a typical electric signal is too high to provide for satisfactory accuracy of measurement.

Commercially-available power supplies typically are designed to provide currents and waveforms over a wide range of intensities and frequencies. Therefore, they include a relatively large number of components, which increases the noise in the system. Moreover, the alternating voltage of the power supply grid introduces additional noise. The standard way to reduce noise in power supply is to decrease the bandwidth using a modulated signal and a lock-in amplifier.

Accordingly, the present invention, in some embodiments, provides for a reduction in non-thermal electric signal noise using a variety of means. In some embodiments, the present invention implements a DC power source which is isolated from any external power grid. In some embodiments, the present invention implements a DC power source which is isolated from circuitry containing a relatively large number of electric and/or electronic components, which tend to increase the noise in the signal, such that, e.g., no more than one electronic component is connected in a current path between the DC power source and the Hall effect sensor.

In some embodiments, the present invention provides for reduction of short- and long-term thermal-based fluctuations, based on at least one of physical heat treatment (e.g., using a cryostat and/or a heat sink), heat noise handling based on a known heat-related response curve (e.g., by offsetting using a computer algorithm), and/or output voltage amplification to reduce SNR.

In some embodiments, output voltage amplification is based on using a low-noise amplifier, e.g., a transistor or operational amplifier. In some embodiments, output voltage amplification is based on using a ferromagnetic Hall effect sensor.

In some embodiments, the present invention provides for a reduction in noise and, by extension, of SNR, of an electric signal in the μA range to a level similar to that of a typical mA current, to allow for similarly-accurate current measurement. In some embodiments, the present invention can measure magnetic fields in the range below 0.7 Tesla for very low DC current sources, without the need to modulate the signal.

By way of background, in a Hall effect sensor, a thin strip of metal or a semiconductor has a current applied along it. In the presence of a magnetic field, the electrons in the metal strip are deflected towards one edge, producing a voltage gradient across the short side of the strip (perpendicular to the feed current). The Hall sensor operates as an analog transducer, directly returning a voltage corresponding to the magnetic field. Thus, a Hall sensor can be used to calculate DC current, by measuring the magnetic flux generated by the current. Thus, a Hall sensor can be used to measure increasing magnitude of magnetic field in direction perpendicular to the metallic/semiconductor plane.

The basic relation between Hall voltage, current and magnetic field is given as

V_{Hall}=R_{H}BI/t,

where R_{H} is Hall resistivity, B is the magnetic field, I is the electrical current, and t is a thickness of material. R_{H} may be given as:

R_{H}=rₕ/nq,

where n is the density of charge carriers, q is the carrier charge, and rₕ is the Hall scattering factor, which depends on the material and the dominant charge carrier mechanism.

Generally, power supply circuitry may include two types of noise: (i) non-thermal 1/f (flicker) noise which decrease with the frequency, and (ii) frequency-independent noise which has mainly a thermal origin, i.e., it depends on temperature.

Total noise above the “corner frequency” (F_{C}) is almost a constant. However, below this corner frequency, noise can elevate at 3 dB/octave. This noise called 1/f noise.

As noted above, in some embodiments, the present system provides for a Hall sensor system with a power source configured for reducing at least a non-thermal noise of the circuitry. In some embodiments, a Hall sensor system of the present invention provides for a significant reduction of noise levels in the current applied to the Hall sensor by comprising a DC power source that is isolated from any external power grid.

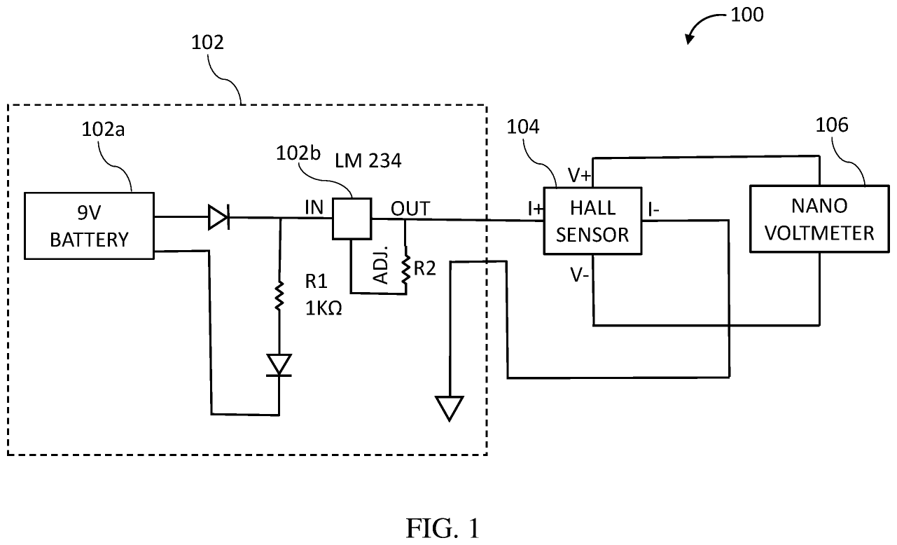

FIG. 1 illustrates an exemplary Hall effect sensor system 100 comprising, in some embodiments, a current source 102, a Hall sensor 104, and a voltage detector 106. Current source 102 comprises, in some embodiments, a DC power source, such as a 9-volt battery 102a, which may be used as the source of current applied to a Hall sensor so as to isolate the measurement circuitry from the external power grid. The load on the power source should be no more than 9V, and ideally less, in order to reduce noise. To create a constant current regardless on the voltage load, current source 102 may use an adjustable current source 102b, in this case, a Texas Instruments LM234 (see http://www.ti.com/product/LM234).

The formula which connects output current and resistivity in resistor R₂ may be given as:

Iₒᵤₜ=(227 mV/K)/R₂.

In system 100, if the voltage load is no larger than a few millivolts, and fluctuations in the load are small, the noise level will also be very small.

Hall sensor 104 in system 100 may be, e.g., a gallium arsenide (GaAs) Hall sensor. A nanovoltmeter 106 is provided for measuring the output voltage of Hall sensor 104 in response to the presence of a magnetic field.

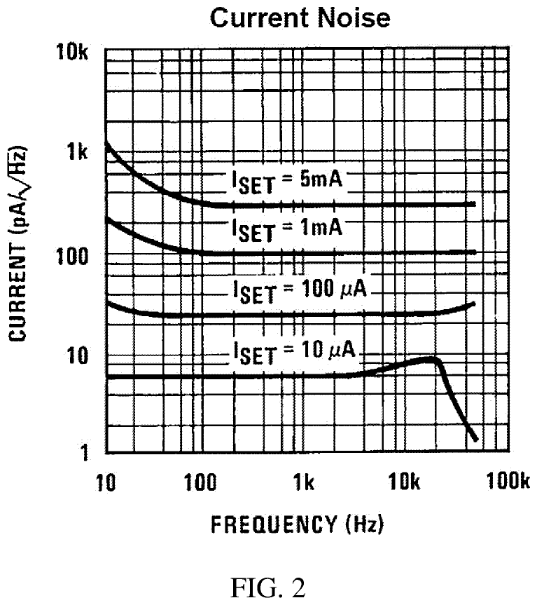

FIG. 2 illustrates the noise spectral density of current source 102 as a function of frequency, in the range of 10 Hz-100 kHz (shown in the logarithmic scale). As can be seen, the 1/f noise decreases until the corner frequency is reached, and then levels off to a constant value. The corner frequency is shown as around 100 Hz for the 5 mA and 1 mA current sources. For the 100 μA current source, the corner frequency lies between 10 and 100 Hz, and is expected to reach approximately 100 pA/\sqrt{H_{Z}} around 1 Hz. For the 10 μA current source, the noise curve is flat and is not expected to change drastically between 1 and 10 kHz. The noise curve for a 1 μA current source is not shown, but is expected to be lower than the noise level for the 10 μA curve.

For comparison purposes, a Keithley 6221 AC/DC current source (see http://www.keithley.com) has an approved broadband RMS noise levels on the order of nA/\sqrt{H_{Z}}. Accordingly, the level of 1/f noise achieved by current source 102 is three orders of magnitude smaller than a comparable industrial current source connected to the external grid.

In some embodiments, the noise generated by the Hall sensor 104 circuitry is of the thermal type. In some embodiments, such circuitry may comprise the Hall sensor 104 itself, as well as cables (e.g., coaxial cables) and electrical connectors. The main type of broadband resistance noise at room temperature in DC circuits is Johnson-Nyquist noise. The noise level of the sensor voltage equals

V=\sqrt{4k_{b}TRΔf},

where k_{b} is the Boltzmann constant, T is the temperature, R is the resistance, and Δf is the frequency bandwidth. See, e.g., G. Jung, et al.; Magnetic Noise Measurements Using Cross-Correlated Hall Sensor Arrays; 2001; http://dx.doi.org/10.1063/1.1340866.

In some embodiments, heat noise is handled by system 100 using at least one of a cryostat and/or a heat sink. To assess the accuracy of the disclosed invention and the influence of measurements of thermal noise, a Hall effect system of the present invention, similar to system 100 described above with reference to FIG. 1, was placed within a liquid nitrogen-cooled cryostat to perform voltage and resistance noise measurements.

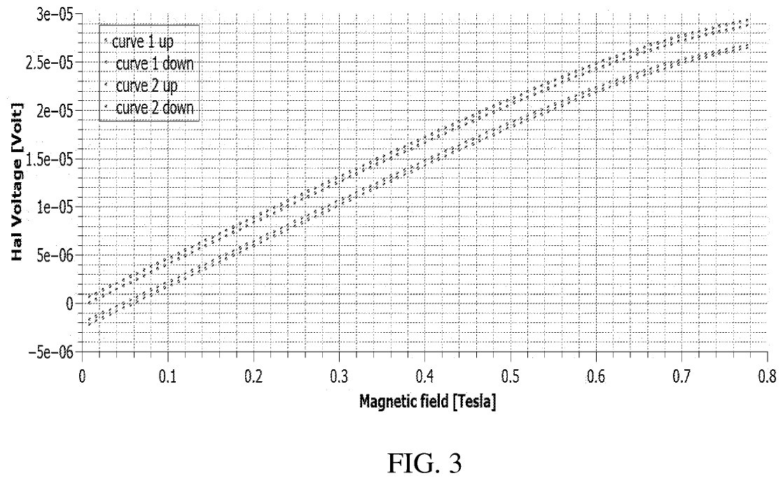

FIG. 3 illustrates the effect of thermal fluctuations on Hall response. As can be seen, there is a thermal drift between the two curves. Each curve consists of two parts: a first part reflects the Hall response when the magnetic field increases from zero to a maximum value (“up”), and a second part where the magnetic field decreased from the maximum value back to zero (“down”). As can be seen, changes occur between the first and second curves, but not between “up” and “down” part of the same curve. This is mainly because the thermal drift is slower than the time it takes for system 100 to perform measurements when changing magnetic field from zero to maximum and back.

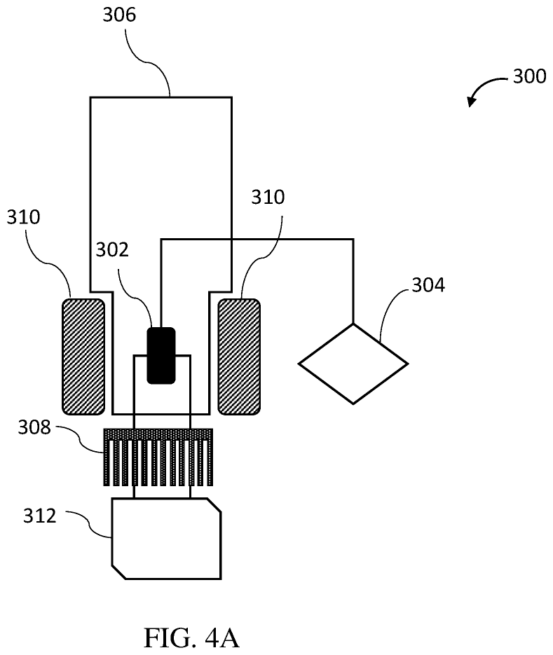

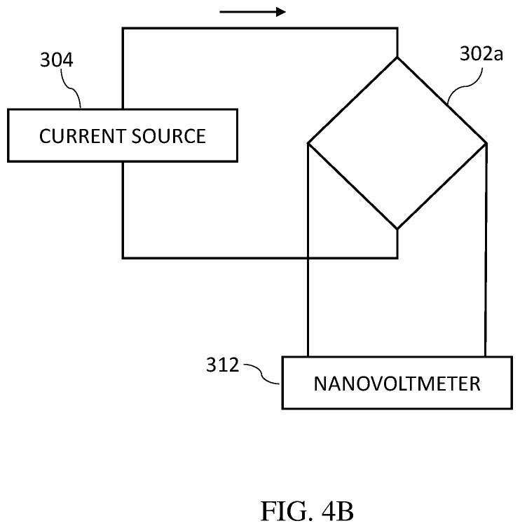

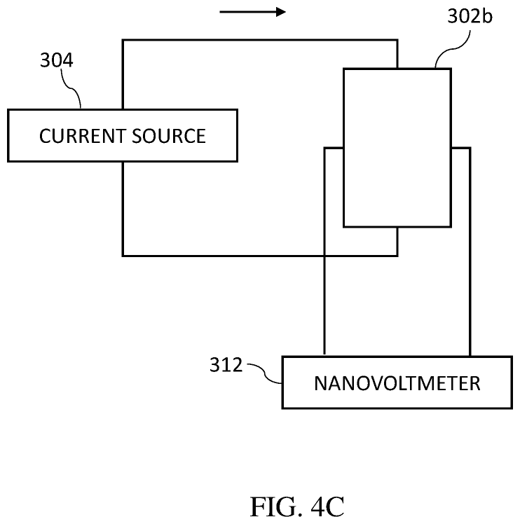

FIG. 4A illustrates an exemplary system 300 wherein thermal-related noise is handled through the use of a cryostat and/or a heat sink. In some embodiments, system 300 comprises Hall sensor 302, a current source 304, a nitrogen cryostat 306, and a heat sink 308. A magnetic field generator 308 and a nanovoltmeter 310 are further provided.

FIGS. 4B-4C illustrates two different Hall effect sample arrangements which may be used in conjunction with system 300:
A Van der Pauw sample arrangement 302a (see, e.g., H. Blanchard, et al., “Highly sensitive Hall sensor in CMOS technology”, Sens. Actuators A: Phys. 82 (1) (2000) 144-148; K. A. Borup, et al., “Measuring anisotropic resistivity of single crystals using the van der Pauw technique”, Phys. Rev. B 92 (4) (2015) 45210; B. Schumacher, et al., “DC conductivity measurements in the Van der Pauw geometry”, IEEE Trans. Instrum. Meas. 52 (2) (2017)); and
A Hall bar arrangement 302b (see, e.g., C. Yang, “A Study of Electrical Properties in Bismuth Thin Films”, University of Florida, Gainesville, 2008, pp. 18.; Z. Yang, et al., “Electronic transport and spatial/temporal photocurrent in monolayer molybdenum disulfide grown by CVD”, APS March Meeting Abstracts (2016)).

In the Van der Pauw arrangement 302a, the electrical contacts are connected to the boundaries of a square sample. In the Hall bar arrangement 302b, voltage is measured diagonally, wherein the current flows through an elongated plate and the Hall voltage is measured at the cross section. In both cases, the voltage is measured perpendicular to the current, and the voltage and current contacts are separated. Such configurations are called four-point probes. Measurements of resistance effects in these configurations are only related to the properties of the sample, not to the measurement circuit.

In each case, the sample is attached to a holder with connected wires. The holder is inserted into the evacuation area of the cryostat 306. This allows holding the sample either in vacuum or at a low constant gas pressure. In some embodiments, the gas delivered to this region is pure helium. In some embodiments, the outer walls of the cryostat 306 are cooled by liquid nitrogen. In some embodiments, the inside cools to a low of 77 degrees Kelvin, so the helium remains gaseous at a pressure of a few millibars.

In some embodiments, the temperature of the area containing the sample is adjustable from 77 to 300 Kelvin, by cooling the gas or adjusting the heater, with the help of a Cernox temperature sensor and a controller from Lake Shore Cryotronics, Inc. (see, http://www.lakeshore.com/Pages/Home). This control system stabilizes the sample area to a constant temperature within 0.1 Kelvin.

In some embodiments, measurements of the Hall voltage are performed under a constant magnetic field adjustable from 0.0 to 0.8 Tesla, in both directions. In some embodiments, the sample used is the HSP-T Hall Sensor from Cryomagnetic, Inc. (see http://www. cryomagnetics.com). The sample type is a Hall bar with one voltage output. The sample is completely isolated from the external environment in the evacuation chamber of cryostat 306, which makes it possible to avoid oxidation. Because the dependence of the Hall voltage on the magnetic field is known with respect to the sample, the measurements can be compared with those the specifications of the manufacturer. As described above, the Hall voltage depends on the magnetic field, the current, the charge of the carriers, the population density of the charge carriers, and the thickness of the sample.

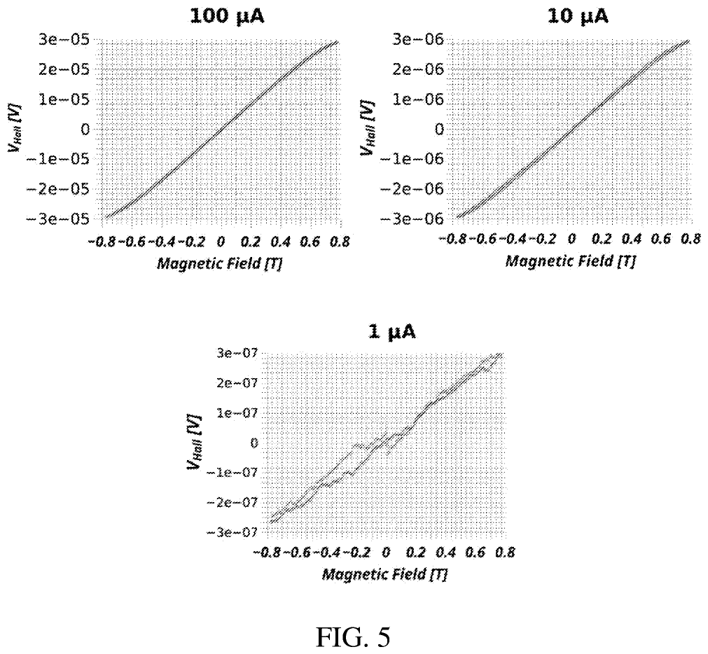

Based on manufacturer specifications, the Hall bar calibration sample has a linear Hall effect when the magnetic field is perpendicular to the current passing through the sample. The manufacturer provides the ratio of the Hall voltage to the magnitude of the magnetic field for a current of 100 mA. In order to test system 300 to assess its sensitivity, the Hall voltage was measured as a function of the external magnetic field using the four-point probe arrangement. In view of a base assumption that the density of carriers does not depend on the current, this relation can be measured for different currents, to check whether it is proportional to the values identified by the manufacturer. Thus, the Hall effect was measured under three currents: 100 mA, 10 mA, and 1 mA. The dependencies of the Hall voltage as function of magnetic field are shown in FIG. 5. As can be seen, there is approximately a linear dependence of the Hall voltage on magnetic field for all current values. Table 1 below shows a comparison of the slopes of the Hall effects measured at all currents to the slope provided by the manufacturer at 100 mA. Statistical errors on the slopes were derived from least-squares linear fits.

TABLE 1
Comparison of Hall Effect Slopes.

| | | | | | | | 100 mA | |
|---|---|---|---|---|---|---|---|---|
| Current | 1 mA | | 10 mA | | 100 mA | | (Manuf.) | |
| V_{H}/T | 0.371 | mV/T | 3.955 | mV/T | 39.85 | mV/T | 39.3 | mV/T |
| 1(V_{H}/T) | 1.5 | nV/T | 6.5 | nV/T | 80 | mV/T | 80 | mV/T |

| | | | | |
|---|---|---|---|---|
| 1(V_{H}/T)/V_{H}/ | 0.42% | 0.16% | 0.2% | 0.2% |
| T*100% | | | | |

As can be seen, the slopes at 1 mA and 10 mA differed from the slope at 100 mA by factors of 107 and 10.07, respectively. These deviations were very close to the expected factors of 100 mA and 10 mA. The most precisely-determined slope in this series of measurements was for the 10 mA current, which had a relative error of only 0.16%.

Table 2 below shows the uncertainties in the slopes as directly proportional to the root-mean-squared error (RMSE) of the Hall voltage measurement:

TABLE 2
RMSE and Hysteresis Deviation for Current Sources at 300K.

| Current | 1 mA | | 10 mA | | 100 mA | |
|---|---|---|---|---|---|---|
| RMSE | 10.4 | nV | 48.7 | nV | 530 | nV |
| Hysteresis Deviation | 0.09 | mV | 0.1 | mV | 0.6 | mV |

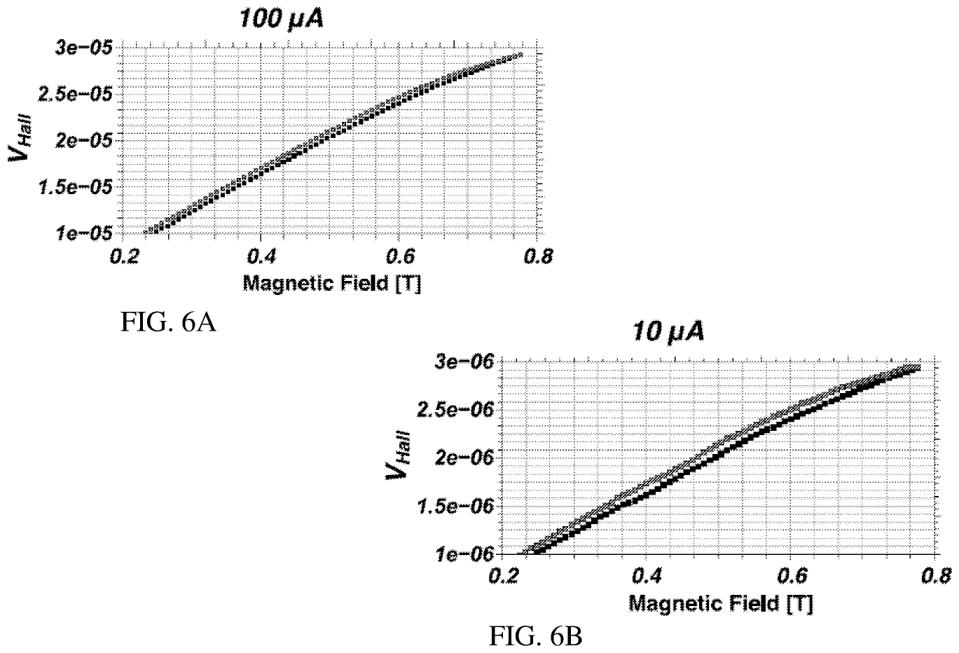

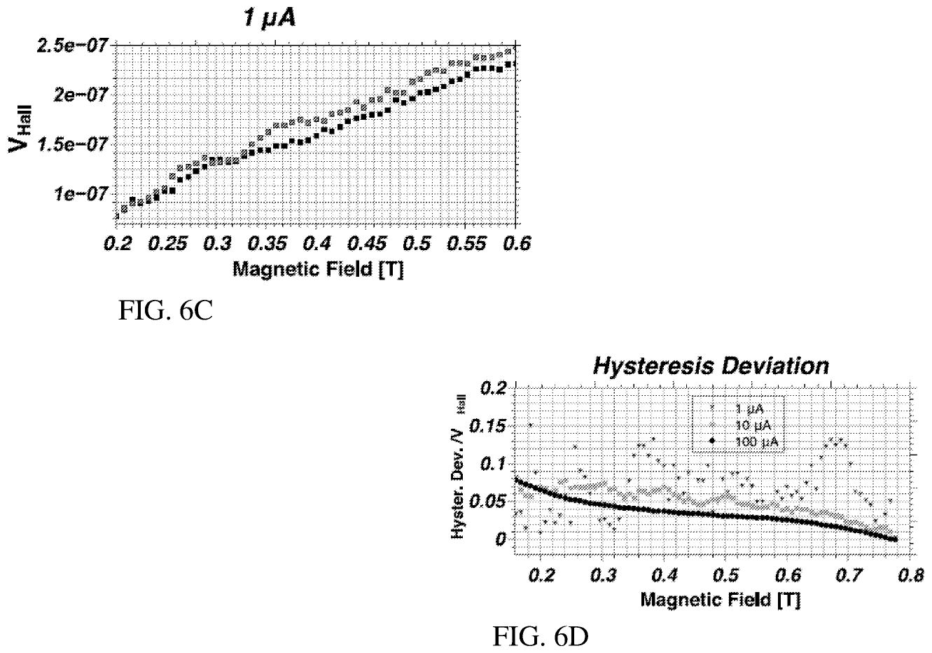

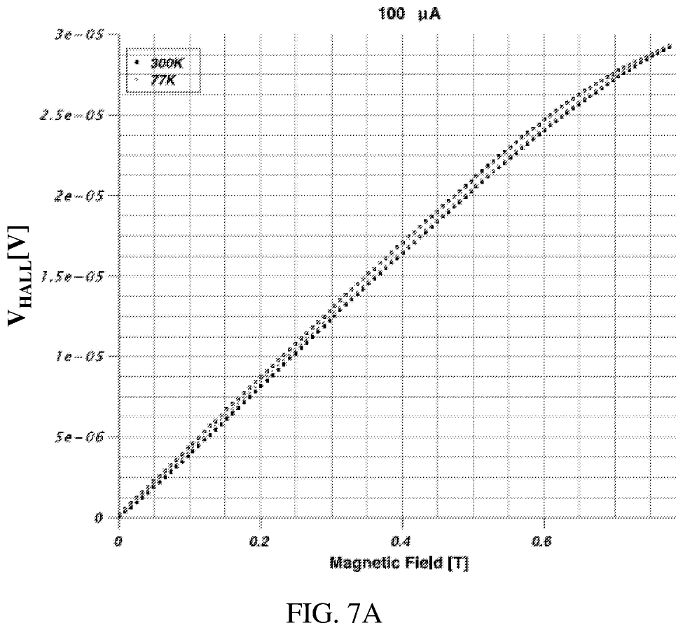

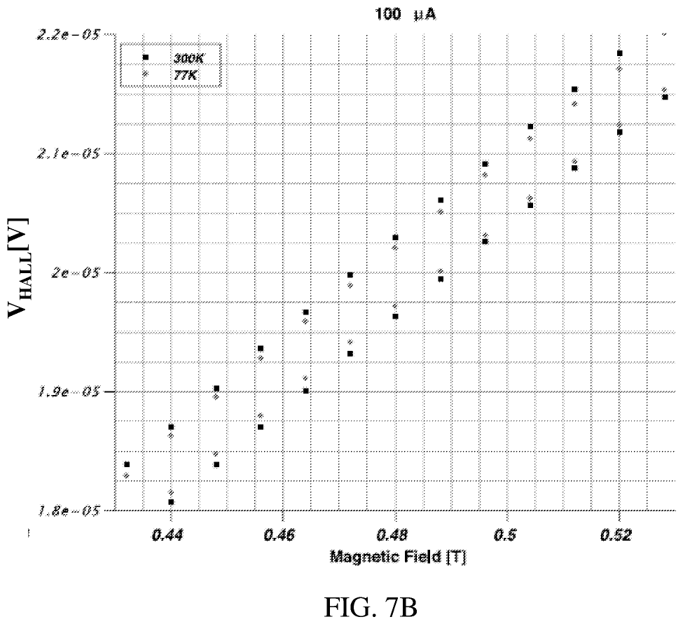

RMSE, measured in nanovolts, defines the real limit of the ability to resolve nonlinear phenomena in the sample. For example, the Hall voltage curve displays hysteresis, which is differently-shaped for increasing and decreasing magnetic fields. One possible source of hysteresis is a small amount of spontaneous magnetization in the sample. The manufacturer does not emphasize the hysteresis deviation, but this effect is well known in the literature. FIGS. 6A-6D show plots of the hysteresis deviation normalized by Hall voltage for all currents levels. The hysteresis deviations were a major source of uncertainty in the slopes. Table 2 above reports the maximal separations in Hall voltage due to hysteresis. The hysteresis deviation was larger than the precision of the voltage measurements, characterized by the RMSE. As the current decreased from 100 mA to 10 mA, the normalized hysteresis deviation did not change drastically, but it strongly increases at 1 mA. In the experiment, 10 mA is the minimal current which gives a linear Hall effect. As mentioned before, the purpose of the experiment was to assess know whether or not the noise in system 100 is thermal. To answer this question, measurements were performed with a 100 mA current source at 300 K and at 77 K. FIGS. 7A-7B show the results, wherein at 77 K, the sensor has almost exactly the same Hall voltage and Magnetic field dependence, with a little lower error rate. These results are summarized in Table 3 below.

TABLE 3
Hall coefficients for 1 mA, 10 mA, 100 mA current sources.

| Temperature | 300K | | 77K | |
|---|---|---|---|---|
| V_{H}/T | 39.85 | mV/T | 39.68 | mV/T |
| 1(V_{H}/T) | 81 | nV/T | 78 | mV/T |

| | | |
|---|---|---|
| 1(V_{H}/T)/V_{H}/T*100% | 0.203% | 0.197% |

Comparing these results to the ones in Table 1, it can be seen that reducing the noise by cooling has much less effect than simply choosing a lower current source with lower 1/f noise. This is one additional proof that the main part of the noise is not thermal.

In some embodiments, thermal-related noise may be offset through dynamic adjustment of the output voltage V_{HALL}. For example, a computer algorithm may be employed to dynamically adjust the V_{HALL} offset according to, e.g., a known response curve, as a function of temperature change. In some embodiments, in the case of fast thermal fluctuations, measurements can be averaged over specified time windows.

In some embodiments, a low-noise amplifier is used to amplify the output voltage V_{HALL}.

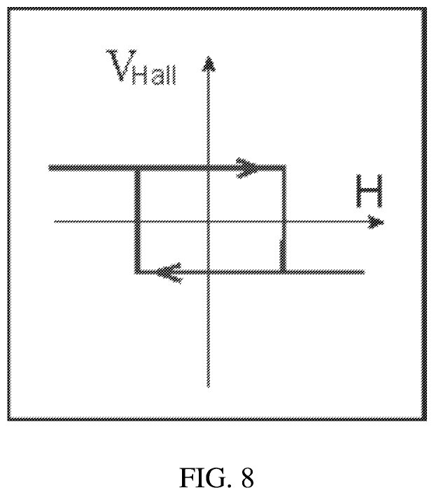

In some embodiments, a ferromagnetic Hall sensor may provide for amplified output voltage V_{HALL}. The ferromagnetic Hall effect leads to a bi-directional Hall voltage response under magnetic field. Depending on such factors as material structure, composition, defects concentration, and/or temperature, among others, the ferromagnetic Hall effect may have stronger influence than the normal Hall effect. For example, it was demonstrated that for certain ferromagnetic materials, the effect can be strongly enhanced near their Curie temperature (ferromagnetic-paramagnetic transition). Accordingly, in some embodiments, a ferromagnetic-based Hall sensor can provide for relatively high Hall response in low current and/or low magnetic field situations. FIG. 8 illustrates the ferromagnetic Hall effect. For more information regarding ferromagnetic materials, see, e.g., D. Cheskis, A. Porat, L. Szapiro, O. Potashnik, and S. Bar-Ad, “Saturation of the ultrafast laser-induced demagnetization in nickel”, Phys. Rev. B—Condens. Matter Mater. Phys. 72, (2005); M. Elazar, M. Sahaf, L. Szapiro, D. Cheskis, and S. Bar-Ad, “Single-pulse magneto-optic microscopy: A new tool for studying optically induced magnetization reversals”, Opt. Lett. 33, 2734 (2008).

### Temperature Sensor Implementation

In some embodiments, the present disclosure provides for a non-contact Hall-effect-based temperature sensor which may be placed externally to a liquid tank and measure liquid temperature. The disclosed temperature sensor provides for a linear response curve across a wide range of working temperatures, while requiring very low current for operation.

In some embodiments, the present Hall-effect-based temperature sensor is based on a linear relationship between a temperature measurement and an output voltage of a Hall effect sensor.

In some embodiments, the present Hall-effect-based temperature sensor enables temperature measurement of a liquid contained in a tank based on measuring a temperature of an external portion of the tank, based on a known correlation.

In some embodiments, the present Hall-effect-based temperature sensor uses an off-grid DC power source, and consumes a low current in the micro-amperes range.

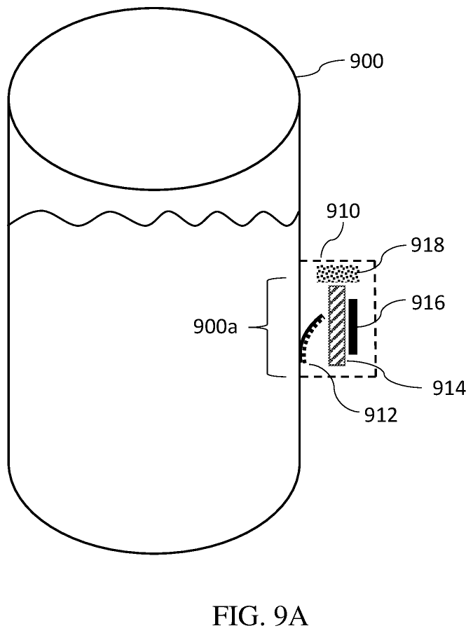

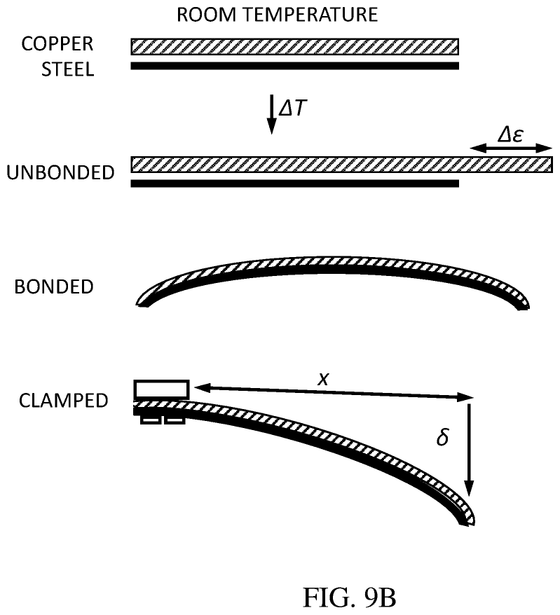

FIG. 9A schematically illustrates a liquid heating system comprising a tank 900, and external temperature sensing unit 910.

The following description will discuss in extensive detail an application of the present temperature sensor with respect to liquid tank temperature measuring applications. However, the present temperature sensor may be advantageously deployed in any application where accurate, linear temperature sensing is required combined with low power consumption and independence of the power grid.

In some embodiments, temperature sensing unit 910 may be coupled externally, to an outside wall area of tank 900. In some embodiments, temperature sensing unit 910 comprises a magnetized element 912, a Hall effect sensor 914, and a DC power source (e.g., DC battery) 916. In some embodiments, temperature sensing unit 910 may also comprise permanent magnet 918.

As noted above, a Hall effect sensor is a transducer that varies its output voltage in response to a magnetic field generated by an electric current. A Hall effect sensor generates an output voltage perpendicular to the direction of current flowing through the sensor, wherein the current is induced by the presence of a magnetic field.

In some embodiments, magnetized element 912 is configured to be thermally-coupled to, e.g., a tank, such as a water or any liquid-containing tank. In some embodiments, magnetized element 912 is in thermal communication with a liquid contained within tank 900, directly or indirectly. In some embodiments, magnetized element 912 is thermally coupled to a liquid contained within tank 900, such that a change in the temperature of the liquid causes a proportional change in a temperature of magnetized element 912.

In some embodiments, the thermo-coupling of magnetized element 912 is to a liquid contained within tank 900, such that magnetized element 912 is in direct thermal contact with the liquid inside tank 900. In other implementations, magnetized element 912 is in thermal contact with a portion of tank 900, e.g., outside wall area 900a, wherein a correlation between a liquid temperature and wall area 900a is known or may be established, to provide an indication of internal liquid temperature based on measuring a temperature of wall area 900a. In other examples, other ways of thermally coupling magnetized element 912, directly or indirectly, to tank 900 and/or a liquid contained therein may be employed.

In some embodiments, magnetized element 912 is configured to convert a temperature change sensed by magnetized element 912 into mechanical displacement. In some embodiments, magnetized element 912 is a bimetallic element as depicted in FIG. 9B. Thus magnetized element 912 consists of two strips of different metals (e.g., steel and copper) which expand at different rates as they are heated. The different expansions force the flat strip to bend one way if heated, and in the opposite direction if cooled below its initial temperature. The metal with the higher coefficient of thermal expansion is on the outer side of the curve when the strip is heated and on the inner side when cooled. Accordingly, magnetized element 912 may undergo mechanical displacement under temperature changes of the liquid inside tank 900. In some embodiments, such mechanical displacement may, e.g., comprise movement of at least a portion of magnetized element 912 in relation to Hall effect sensor 916.

In some embodiments, a mechanical displacement of magnetized element 912 in relation to Hall effect sensor 916 may affect a magnetic field which passes through Hall effect sensor 916. In some embodiments, the magnetic field passing through Hall effect sensor 916 comprises a combined magnetic field comprising a magnetic field generated by magnetized element 912 and a magnetic field generated by permanent magnet 918. In some embodiments, temperature sensing unit 910 is configured such that a mechanical displacement of magnetized element 912 causes a corresponding change in a magnetic field which passes through Hall effect sensor 916, and thus a linear output voltage change in Hall effect sensor 916.

In some embodiments, an output voltage of Hall effect sensor 916 may be measured and translated into a temperature indication based, at least in part, on a known correlation.

In some embodiments, the present temperature sensing unit 910 may provide for low power consumption. In some embodiments, a DC power source of 1.15 Ah (e.g., a AAA battery) may provide for 1.3 years of service using a 100 mA current, and 13.1 years of service using a 100 μA current.

### Experimental Results

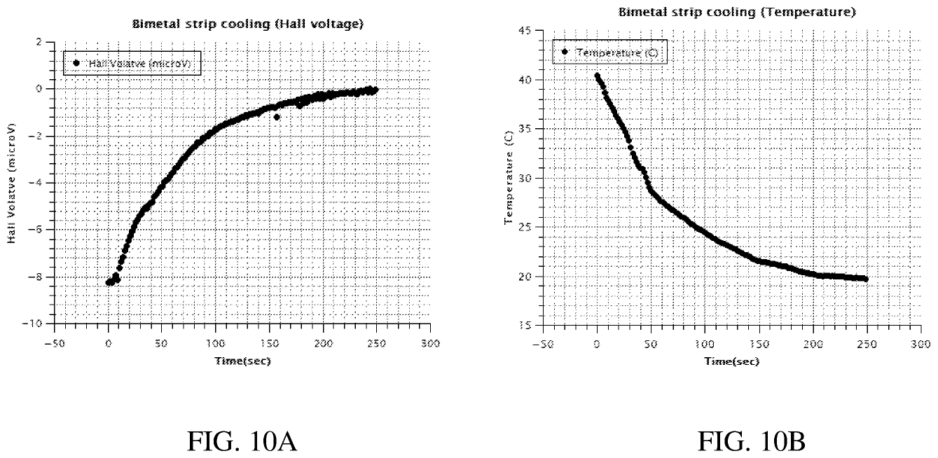

FIGS. 10A-10B plot the temperature of magnetized element 912 as a function of time and an output voltage of Hall effect sensor 916 as a function of time, using a 100 μA current source.

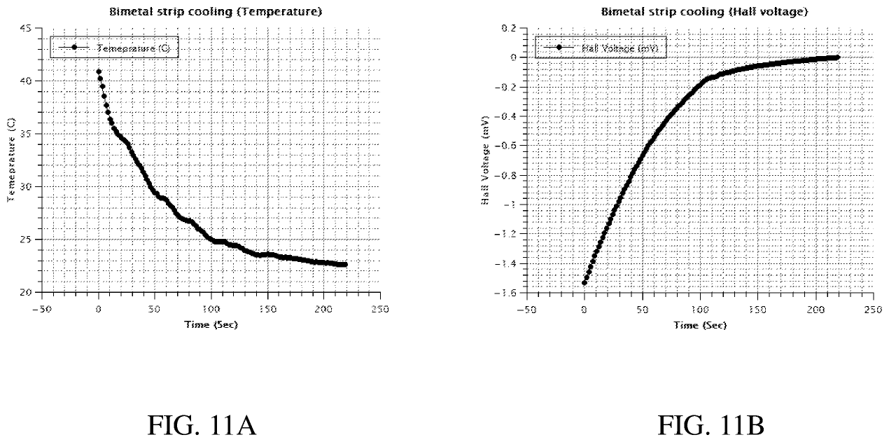

FIGS. 11A-11B plot the temperature of magnetized element 912 as a function of time and an output voltage of Hall effect sensor 916 as a function of time, using a 100 mA current source.

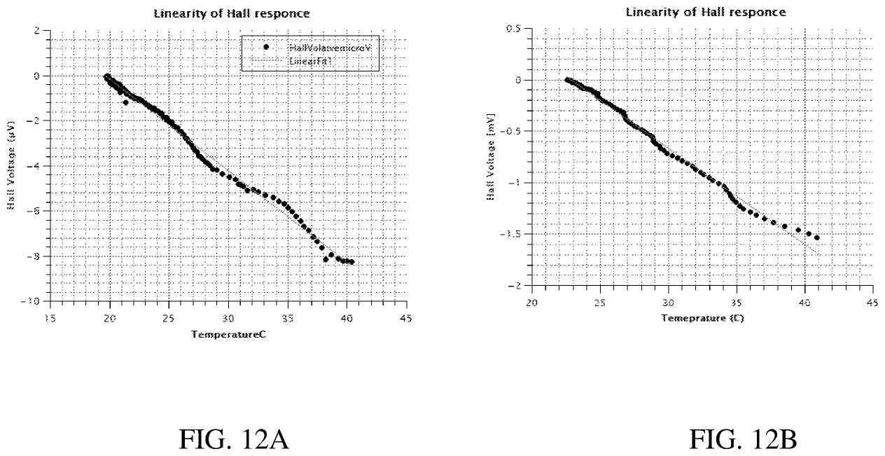

FIGS. 12A-12B show a relationship between an output voltage of Hall effect sensor 916 and a temperature of magnetized element 912 using a 100 μA current source (FIG. 12A) and a 100 mA current source (FIG. 12B). As can be seen, there is a linear relationship between an output voltage of Hall effect sensor 916 and a temperature of magnetized element 912.

These measurements indicate a maximum deviation of ±1° C. using a 100 mA current source, and ±2° C. using a 100 μA current source.

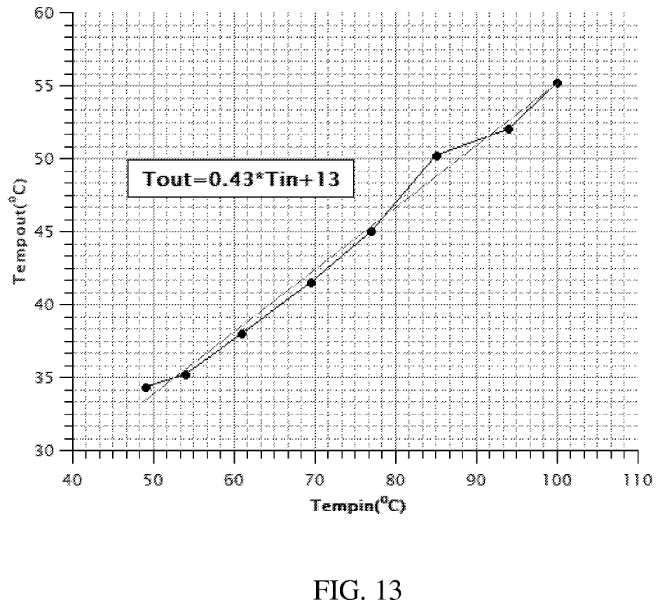

FIG. 13 shows a relationship between a temperature of a liquid inside tank 900 and a temperature of, e.g., wall area 900a measure externally of tank 900. In this case, there is established an approximate ratio of 2.3:1.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiments, the practical application or technical improvement over technologies found in the marketplace, or to enable others of ordinary skill in the art to understand the embodiments disclosed herein. Accordingly, it is shown that a standard commercially-available Hall sensor can exhibit a linear response for current in the microampere range.

1. A system comprising:
a Hall effect element; and
a direct current (DC) source connected to said Hall effect element, wherein:
(i) said DC source is isolated from an external power grid, and
(ii) no more than two electronic component are connected in a current path between said DC source and said Hall effect element.

2. (canceled)

3. The system of claim 1, wherein no more than one electronic component is connected in said current path between said DC source and said Hall effect element.

4. The system of claim 1, wherein said electronic components are selected from a group consisting of a current regulator and a resistor.

5. The system of claim 1, wherein said DC source is connected to said Hall effect element using one of: a four-point probe arrangement and a Hall bar arrangement.

6. The system of claim 1, further comprising at least one of (i) a heat sink and (ii) a cryostat, each configured to reduce a temperature of said Hall effect element.

7. The system of claim 5, further configured to adjust an output voltage of said Hall effect element based, at least in part, on a known output voltage response curve of said Hall effect element as a function of said temperature.

8. The system of claim 1, wherein said Hall effect element has a known Hall coefficient.

9. The system of claim 1, further comprising a low noise amplifier configured to amplify said output voltage.

10. (canceled)

11. (canceled)

12. (canceled)

13. A method comprising:
providing a Hall effect element;
connecting said Hall effect element to a direct current (DC) source, wherein:
(i) said DC source is isolated from an external power grid, and
(ii) no more than two electronic component are connected in a current path between said DC source and said Hall effect element;
placing said Hall effect element in the presence of a magnetic field, such that said magnetic field passes through said Hall effect element in a specified direction; and
measuring an output voltage of said current Hall element.

14. (canceled)

15. The method of claim 13, wherein no more than one electronic components is connected in said current path between said DC source and said Hall effect element.

16. The method of claim 13, wherein said electronic components are selected from a group consisting of: a current regulator and a resistor.

17. (canceled)

18. The method of claim 13, wherein said Hall effect element is coupled to at least one of (i) a heat sink and (ii) a cryostat, each configured to reduce a temperature of said Hall effect element.

19. The method of claim 18, further comprising adjusting said output voltage of said hall effect element based, at least in part, on a known output voltage response curve of said Hall effect element as a function of said temperature.

20. (canceled)

21. The method of claim 13, further comprising amplifying said output voltage using a low noise amplifier.

22. (canceled)

23. (canceled)

24. The method of claim 13, wherein said magnetic field is known, the method further comprising calculating a current of said DC source based, at least in part, on said measured output voltage, wherein said current is in the microampere range.

25. (canceled)

26. A system comprising:
a magnetic element configured to displace mechanically in response to temperature changes;
a Hall effect element placed within a first magnetic field generated by said magnetic element, such that said first magnetic field passes through said Hall effect element in a specified direction; and
a direct current (DC) source connected to said Hall effect element, wherein:
(i) said DC source is isolated from an external power grid, and
(ii) no more than one electronic component is connected in a current path between said DC source and said Hall effect element.

27. The system of claim 26, wherein said magnetic element comprises a magnetized bi-metallic element.

28. The system of claim 26, further comprising a permanent magnet, wherein said Hall effect element is also placed within a second magnetic field generated by said permanent magnet.

29. The system of claim 26, wherein said magnetic element is thermally-coupled to a liquid tank, wherein a change in a temperature of a liquid contained in said liquid tank causes said machinal displacement, and wherein a first correlation between said change in said temperature and said mechanical displacement is known.

30. The system of claim 26, wherein said mechanical displacement causes a change in said first magnetic field, and wherein a second correlation between said mechanical displacement and said change in said first magnetic field is known.

31-46. (canceled)
